(19) United States
(12) Patent Application Publication
(10) Pub. No.: US 2026/0167845 A1
(43) Pub. Date: Jun. 18, 2026

(54) SLURRY COMPOSITION AND METHODS OF MANUFACTURING SEMICONDUCTOR DEVICE AND SEMICONDUCTOR PACKAGE BY USING THE SAME

(71) Applicant: Samsung Electronics Co., Ltd., Suwon-si (KR)

(72) Inventors: Junghun Kim, Suwon-si (KR); Eungchul Kim, Suwon-si (KR); Hojin Jeong, Suwon-si (KR)

(21) Appl. No.: 19/410,845

(22) Filed: Dec. 5, 2025

(30) Foreign Application Priority Data
Dec. 12, 2024 (KR) 10-2024-0185078

(51) Int. Cl. C09G 1/02; H10P 52/40; H10W 20/00

(52) U.S. Cl. CPC C09G 1/02; H10P 52/403; H10W 20/062

(57) ABSTRACT

An example of a slurry composition includes a polishing particle; and at least one of a polymer including a hydrophobic chain or a nonionic surfactant having a hydrophilic-lipophilic balance (HLB) value of about 3 to about 10 inclusive.

### CROSS-REFERENCE TO RELATED APPLICATION

This application is based on and claims priority under 35 U.S.C. § 119 to Korean Patent Application No. 10-2024-0185078, filed on Dec. 12, 2024, in the Korean Intellectual Property Office, the disclosure of which is incorporated by reference herein in its entirety.

### BACKGROUND

In processes of manufacturing a semiconductor device and a semiconductor package, a chemical mechanical polishing process is mainly used for surface polishing of a metal layer and the like. Along with an increase in the integration of a semiconductor device and a semiconductor package, improvement of the reliability of a polishing process for producing a fine pattern has been gradually significant.

### SUMMARY

The present disclosure relates to a slurry composition and methods of manufacturing a semiconductor device and a semiconductor package by using the same, and more particularly, to a slurry composition for chemical mechanical polishing and a method of manufacturing a semiconductor package by using the same.

The present disclosure provides a slurry composition by which the polishing selectivity between a metal-containing layer and an insulating layer adjacent thereto may be adjusted, and methods of manufacturing a semiconductor device and a semiconductor package by using the same.

In addition, the problems to be solved by the technical idea of the present disclosure are not limited to the problems mentioned above, and other problems could be clearly understood by those of ordinary skill in the art from the description below.

According to an aspect of the present disclosure, a slurry composition includes a polishing particle and at least one of a polymer including a hydrophobic chain and a nonionic surfactant having a hydrophilic-lipophilic balance (HLB) value of about 3 to about 10 inclusive.

According to another aspect of the present disclosure, a method of manufacturing a semiconductor device includes forming a hydrophobic insulating layer on a substrate, forming, on the hydrophobic insulating layer, an object to be polished, and polishing the object to be polished by performing a chemical mechanical polishing process using a slurry composition, wherein the slurry composition includes at least one of a polymer including a hydrophobic chain and a nonionic surfactant having an HLB value of about 3 to about 10 inclusive.

According to another aspect of the present disclosure, a method of manufacturing a semiconductor package includes forming, on a substrate, a redistribution insulating layer which includes a photo imageable dielectric (PID), and in which an opening portion is defined, forming a preliminary redistribution pattern on the redistribution insulating layer while filling the opening portion, and polishing the preliminary redistribution pattern by performing a chemical mechanical polishing process using a slurry composition, thereby forming a redistribution pattern, wherein the slurry composition includes at least one of a polymer including a hydrophobic chain and a nonionic surfactant having an HLB value of about 3 to about 10 inclusive.

### BRIEF DESCRIPTION OF THE DRAWINGS

Implementations of the present disclosure will be more clearly understood from the following detailed description taken in conjunction with the accompanying drawings in which:

FIG. 1 is a partially cut-away perspective view schematically illustrating some components of a polishing apparatus according to implementations;

FIG. 2 is a flowchart illustrating a method of manufacturing a semiconductor device, according to implementations;

FIGS. 3 to 6 are cross-sectional views sequentially illustrating a method of manufacturing a semiconductor device, according to implementations;

FIG. 7 is a cross-sectional view schematically illustrating a semiconductor package formed by a method of manufacturing a semiconductor package, according to implementations; and

FIG. 8 is a flowchart illustrating the method of manufacturing a semiconductor package, according to implementations.

### DETAILED DESCRIPTION

Hereinafter, implementations are described in detail with reference to the accompanying drawings. Like reference numerals in the drawings denote like elements, and thus their repetitive description will be omitted.

In the implementations below, the terms, such as “first” and “second” are not used as limited meanings but used to classify a certain element from another element. In the implementations below, an expression in the singular includes an expression in the plural unless they are clearly different from each other in context.

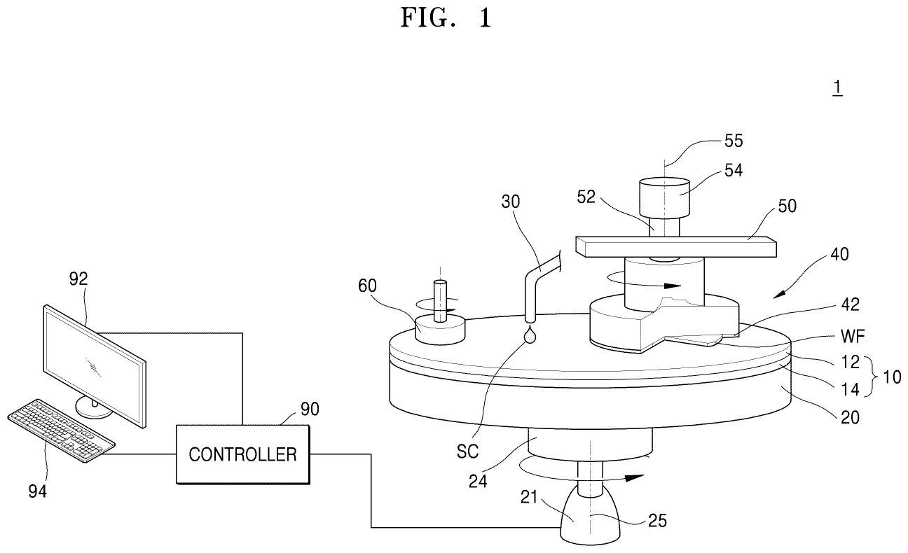

FIG. 1 is a partially cut-away perspective view schematically illustrating some components of a polishing apparatus 1 according to an implementation.

Referring to FIG. 1, the polishing apparatus 1 may be used to polish the surface of a wafer WF in a chemical mechanical polishing (CMP) process. FIG. 1 illustrates the polishing apparatus 1 that is a rotary type.

The polishing apparatus 1 may include a platen 20 that is shaped as a rotatable disc. The platen 20 may be disposed to be rotatable around a central axis 25 of the platen 20 by using a motor 21. For example, the motor 21 may rotate a driving shaft 24 to rotate the platen 20. A polishing pad 10 may be disposed on the upper surface of the platen 20. The polishing pad 10 may include a polishing layer 12 and a support layer 14. The support layer 14 may support the polishing pad 10 such that the polishing pad 10 is attached to the platen 20.

In an implementation, the polishing pad 10 may have a three-dimensional structure. The polishing pad 10 having a three-dimensional structure has reduced conditioning necessity, and thus the durability of polishing particles in the polishing pad 10 may increase.

A layer to be polished, e.g., a metal-containing layer, an insulating layer, or the like, may be formed in the wafer WF. The wafer WF may include a structure for forming an integrated circuit device, a structure for forming a thin-film transistor-liquid crystal display (TFT-LCD), and a structure including various substrates, such as a glass substrate, a ceramic substrate, and a polymer substrate.

The polishing apparatus 1 may include a slurry port 30 through which a slurry composition SC is supplied onto the polishing pad 10. The polishing apparatus 1 may further include a polishing pad conditioner 60. The polishing pad conditioner 60 may be configured to perform a dressing process of periodically polishing and flattening the surface of the polishing pad 10 such that the polishing pad 10 provides constant polishing efficiency.

The polishing apparatus 1 may include at least one carrier head 40. The wafer WF may be loaded on a carrier head 40. The carrier head 40 may be configured to rotate while pressing the wafer WF toward the platen 20 in a state in which the wafer WF loaded on the carrier head 40 is positioned to face the platen 20. Although FIG. 1 shows only one carrier head 40 above the polishing pad 10, a plurality of carrier heads 40 may be disposed above the polishing pad 10. The carrier head 40 may be configured to control pressure to be applied to the wafer WF.

The carrier head 40 may include a retaining ring 42 required to hold the wafer WF. The carrier head 40 may be supported by a support structure 50, e.g., a carousel or a track, and connected to a carrier head rotating motor 54 through a driving shaft 52 to rotate around a central axis 55 of the driving shaft 52.

The polishing apparatus 1 may further include a control system configured to control rotation of the platen 20. The control system may include a controller 90, such as a general-purpose programmable digital computer, an output device 92, such as a monitor, and an input device 94, such as a keyboard. Although FIG. 1 shows a configuration that the control system is connected to only the motor 21, this is merely illustrative, and the control system may also be connected to the carrier head 40 to adjust the pressure or rotating speed of the carrier head 40. In addition, the control system may be connected to the slurry port 30 to adjust supply of the slurry composition SC.

The slurry composition SC according to various embodiments may include at least one of a polymer including a hydrophobic chain and a nonionic surfactant having a hydrophilic-lipophilic balance (HLB) value of about 3 to about 10 inclusive. The nonionic surfactant having an HLB value of about 3 to about 10 inclusive may include a hydrophobic chain.

The slurry composition SC according to implementations may be used to polish a double-layered material including a metal-containing layer and an insulating layer having a hydrophobic surface (hereinafter, the hydrophobic insulating layer).

The slurry composition SC may have a polishing selectivity of the metal-containing layer to the hydrophobic insulating layer of about 20 to about 50. The slurry composition SC may be used to polish the metal-containing layer by using the hydrophobic insulating layer as a polishing stop layer. That is, an object to be polished may be the metal-containing layer. The metal-containing layer may include a copper (Cu) layer, a Cu alloy layer, a titanium (Ti) layer, a tantalum (Ta) layer, a molybdenum (Mo) layer, a Mo alloy layer, a tungsten (W) layer, a W alloy layer, a cobalt (Co) layer, a Co alloy layer, a ruthenium (Ru) layer, a Ru alloy layer, or a combination thereof. For example, the hydrophobic insulating layer may be a hydrophobic polymer layer. In an implementation, the hydrophobic insulating layer may be a photo imageable dielectric (PID).

The polymer including a hydrophobic chain and the nonionic surfactant having an HLB value of about 3 to about 10 inclusive (hereinafter, the nonionic surfactant), which are included in the slurry composition SC, may be adsorbed to the hydrophobic insulating layer during a polishing process. By the polymer including a hydrophobic chain and the nonionic surfactant, which are adsorbed to the hydrophobic insulating layer, other particles, such as a polishing particle, included in the slurry composition have difficulty approaching the hydrophobic insulating layer, and accordingly, the polishing selectivity between the hydrophobic insulating layer and the metal-containing layer may be adjusted. That is, the slurry composition SC according to various implementations may have an appropriate polishing selectivity between the hydrophobic insulating layer and the metal-containing layer by a steric effect.

In an implementation, the molecular weight of the polymer including a hydrophobic chain, which is included in the slurry composition SC, or the molecular weight of the nonionic surfactant included in the slurry composition SC may be about 1,000 to about 10,000 inclusive.

With 1,000 or more of the molecular weight of the polymer including a hydrophobic chain or the molecular weight of the nonionic surfactant, the slurry composition SC may have a high polishing selectivity of the metal-containing layer to the hydrophobic insulating layer through the steric effect described above.

When the polishing selectivity of the metal-containing layer to the hydrophobic insulating layer is high, because polishing may be stopped as soon as the hydrophobic insulating layer is revealed by polishing the metal-containing layer, metal residue may remain on the surface of the hydrophobic insulating layer. In the slurry composition SC according to an implementation, the molecular weight of the polymer including a hydrophobic chain or the molecular weight of the nonionic surfactant may be 10,000 or less, to prevent the generation of the metal residue due to strong polishing stop performance of the slurry composition SC.

In an implementation, the polymer including a hydrophobic chain may include at least one functional group of methyl, ethyl, butyl, alkyl, fluorocarbon, cyclohexane, phenyl, benzoyl, trifluoromethyl, or cyclopentadiene.

In an implementation, the content of the nonionic surfactant may be about 0.01 weight% to about 0.1 weight% inclusive with respect to the total content of the slurry composition SC.

The slurry composition SC according to an implementation may further include a polishing particle, deionized water, a cationic chemical, a chelate chemical, a pH modifier, an oxidizer, and/or biocide.

The polishing particle included in the slurry composition SC may polish the metal-containing layer in a polishing process. In implementations, the polishing particle may be an inorganic oxidative polishing particle. For example, the polishing particle may include silica, alumina, ceria, titania, zirconia, magnesia, germania, mangania, or a combination thereof.

The deionized water included in the slurry composition SC may be pure water. The content of the deionized water included in the slurry composition SC may not be specifically limited and may be included as residue together with main elements including a metal ion, the cationic chemical, a nonionic polymer, the polishing particle, and the pH modifier in the slurry composition SC.

In implementations, the slurry composition SC may include the cationic chemical for preventing a dishing effect that the metal-containing layer is excessively polished and deformed to a groove or a recessed shape. The cationic chemical included in the slurry composition SC may be a water-soluble cationic chemical. For example, the cationic chemical may include an amphiphilic amino acid, an amine group, or a combination thereof. The amphiphilic amino acid may include, for example, lysin, methionine, glycine, arginine, or a combination thereof. The amine group may include, for example, aminobutyric acid, 4-amino benzoic acid, picolinic acid, 1,2,4-triazole, benzotriazole, or a combination thereof.

In implementations, the chelate chemical included in the slurry composition SC may include at least one of an amino acid and a carboxylic group. The amino acid may be at least one of glycine, aniline, proline, lysin, arginine, or histidine. The carboxylic group may be a citric acid.

The pH modifier included in the slurry composition SC may adjust the pH of the slurry composition SC to be selected within a range of about 2 to about 11.

In implementations, the pH modifier may include potassium hydroxide, acetic acid, nitric acid, hydrogen chloride, ammonium hydroxide, sodium hydroxide, tetramethylammonium hydroxide, or a combination thereof but is not limited thereto.

In implementations, the slurry composition SC may have a pH selected within a range of about 2 to about 11. For example, the slurry composition SC may have a pH of about 4 to about 10 or a pH of about 5 to about 8. To control the pH of the slurry composition SC to a desired value, an appropriate amount of the pH modifier composed of an acid solution and/or an alkali solution may be used. In the slurry composition SC, the pH modifier may be included by as much as the amount required to adjust the slurry composition SC so as to have a requested pH and is not specifically limited.

As a non-limiting example, the oxidizer included in the slurry composition SC may include organic peroxide, such as peracetic acid, perbenzoic acid, or tert-butyl hydroperoxide, a permanganic acid compound, such as potassium permanganate, a dichromic acid compound, such as potassium dichromate, a halogenic acid compound, such as potassium iodate, a nitric acid compound, such as nitric acid or iron nitrate, a perhalogenic acid compound, such as perchloric acid, persulfate, such as sodium persulfate, potassium persulfate, or ammonium persulfate, percarbonate, such as sodium percarbonate or potassium percarbonate, carbamide peroxide, heteropoly acid, or the like.

The biocide may prevent the slurry composition SC and/or the object to be polished from being contaminated by microorganisms. In an implementation, the biocide may include an organo tin compound, salicylanilide, formaldehyde, a quaternary ammonium compound, 2-bromo-2-nitropropane-1,3-diol (bronopol), 2,2-dibromo-3-nitrilopopionamide (DBNPA), isothiazolone, carbamate, quaternary phosphonium salt (e.g., tetrakis(hydroxymethyl)phosphonium sulfate (THPS)), sodium chloride, sodium hypochlorite, trichloroisocyanuric acid, dichloroisocyanuric acid, calcium hypochlorite, lithium hypochlorite, chlorine dioxide, ozone, hydrogen peroxide, or a combination thereof but is not limited thereto.

When the biocide is included in the slurry composition SC, the content of the biocide may be about 0.001 weight% to about 10 weight% with respect to the total weight of the slurry composition SC. In an implementation, the content of the biocide may be about 0.001 weight% to about 5 weight %, about 0.001 weight % to about 3 weight %, or about 0.001 weight % to about 1 weight % with respect to the total weight of the slurry composition SC.

The slurry composition SC according to various implementations may include at least one of the polymer including a hydrophobic chain and the nonionic surfactant to induce a steric effect, thereby acquiring an appropriate polishing selectivity between the hydrophobic insulating layer and the metal-containing layer.

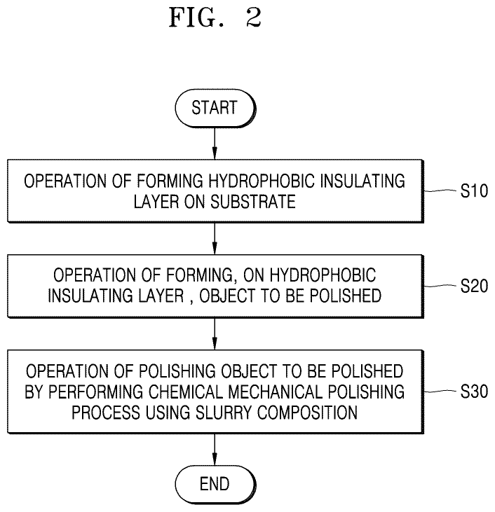

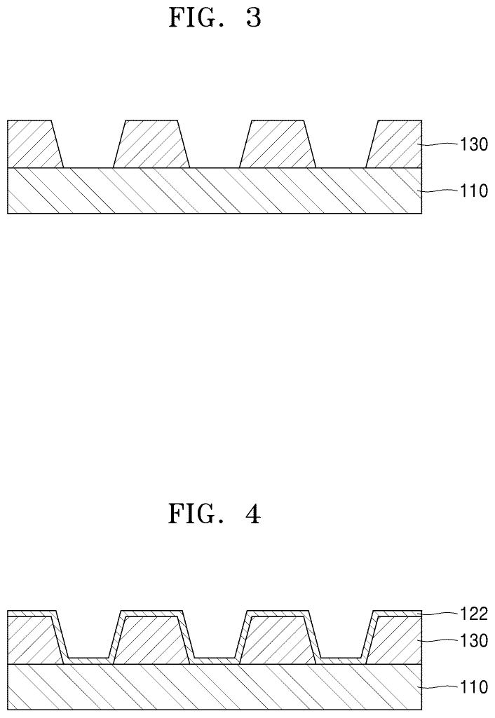

FIG. 2 is a flowchart illustrating a method of manufacturing a semiconductor device, according to implementations, and FIGS. 3 to 6 are cross-sectional views sequentially illustrating the method of manufacturing a semiconductor device, according to implementations.

Referring to FIG. 2, the method of manufacturing a semiconductor device, according to implementations, may include operation S10 of forming a hydrophobic insulating layer on a substrate, operation S20 of forming, on the hydrophobic insulating layer, an object to be polished, and operation S30 of polishing the object to be polished by performing a CMP process using a slurry composition. The slurry composition may include at least one of a polymer including a hydrophobic chain and a nonionic surfactant having an HLB value of about 3 to about 10 inclusive.

Referring to FIGS. 2 and 3, a hydrophobic insulating layer 130 may be formed on a substrate 110 in operation S10. The substrate 110 may include a semiconductor, such as silicon (Si) or germanium (Ge), or a compound semiconductor, such as SiGe, silicon carbide (SiC), gallium arsenide (GaAs), indium arsenide (InAs), or indium phosphide (InP). The substrate 110 may include a conductive area (not shown). The conductive area may include an impurity-doped well, an impurity-doped structure, or a conductive layer. The hydrophobic insulating layer 130 may include an insulating layer, e.g., a PID, having a hydrophobic surface. In an implementation, an opening portion may be defined in the hydrophobic insulating layer 130.

Referring to FIG. 4, a seed layer 122 may be formed on the hydrophobic insulating layer 130. The seed layer 122 is a layer for easily depositing the object to be polished, which is deposited thereafter, and may include a metal material, for example, Cu, Ti, or Ta. In an implementation, the forming of the seed layer 122 may be omitted.

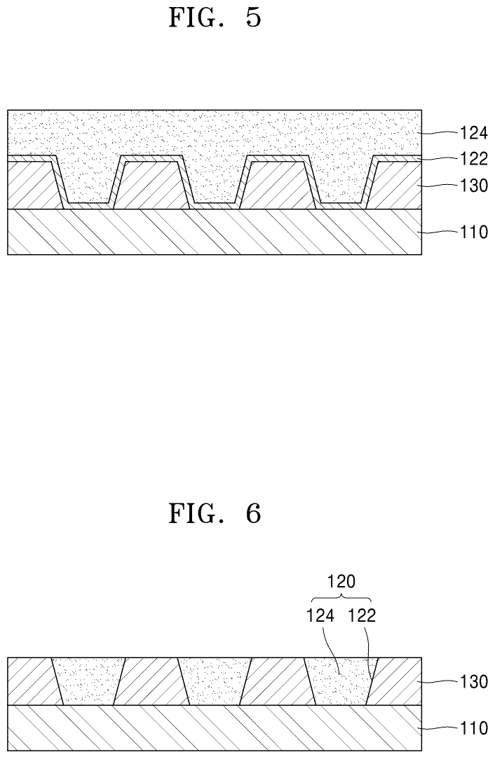

Referring to FIG. 5, a metal material layer 124 that is the object to be polished may be formed on the hydrophobic insulating layer 130 in operation S20. The metal material layer 124 may be disposed on the seed layer 122. At least a portion of the metal material layer 124 may fill the opening portion of the hydrophobic insulating layer 130.

Referring to FIG. 6, the metal material layer 124 that is the object to be polished may be polished through a polishing process using the slurry composition in operation S30. As described above, the slurry composition may include at least one of a polymer including a hydrophobic chain and a nonionic surfactant having an HLB value of about 3 to about 10 inclusive. The polymer including a hydrophobic chain may include at least one functional group among methyl, ethyl, butyl, alkyl, fluorocarbon, cyclohexane, phenyl, benzoyl, trifluoromethyl, and cyclopentadiene. The molecular weight of the polymer including a hydrophobic chain, which is included in the slurry composition, or the molecular weight of the nonionic surfactant included in the slurry composition may be about 1,000 to about 10,000 inclusive. The polishing selectivity of the metal material layer 124 to the hydrophobic insulating layer 130 in the slurry composition may be about 20 to about 50.

Referring to FIG. 6, after the polishing process, the upper surface of the hydrophobic insulating layer 130 may have a same vertical level (e.g., a substantially same vertical level that differs by 30% or less, 20% or less, 10% or less, or 5% or less) as the upper surface of the metal material layer 124 that is the object to be polished. Outside the opening portion of the hydrophobic insulating layer 130, the seed layer 122 on the upper surface of the hydrophobic insulating layer 130 may be removed by the polishing process. The metal material layer 124 and the hydrophobic insulating layer 130 may provide a generally flat upper surface. As described above, when a wiring layer of the semiconductor device is formed by performing (or repeating) the process described with reference to FIGS. 3 to 6, undulation may be prevented.

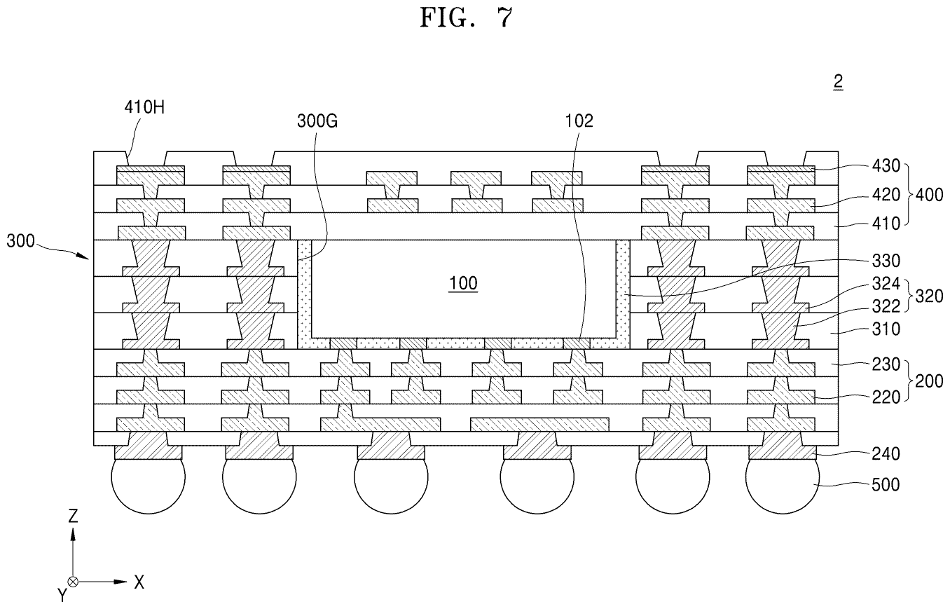

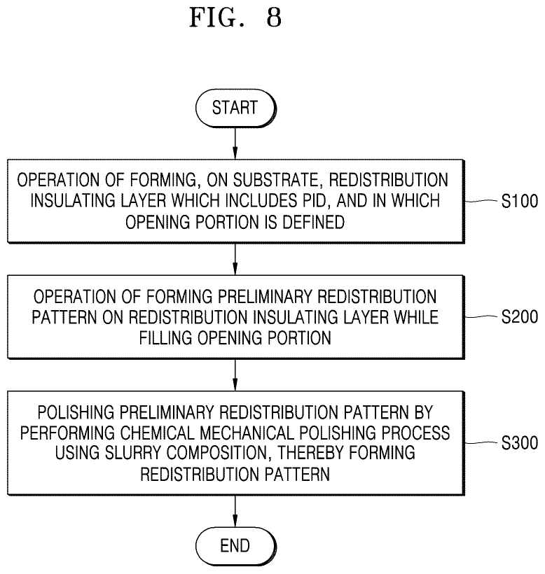

FIG. 7 is a cross-sectional view schematically illustrating a semiconductor package 2 formed by a method of manufacturing a semiconductor package, according to implementations, and FIG. 8 is a flowchart illustrating the method of manufacturing a semiconductor package, according to implementations.

Referring to FIG. 7, the semiconductor package 2 may have a fan-out panel-level package structure. The semiconductor package 2 may include a semiconductor chip 100, a first redistribution structure 200, a connection structure 300, and a second redistribution structure 400. The semiconductor chip 100 may be disposed on the first redistribution structure 200, the connection structure 300 may be disposed on the first redistribution structure 200 to surround the semiconductor chip 100, and the second redistribution structure 400 may be disposed on the semiconductor chip 100 and the connection structure 300. The connection structure 300 may electrically connect the first redistribution structure 200 to the second redistribution structure 400.

In implementations, the first redistribution structure 200 and the second redistribution structure 400 may be formed by a redistribution process. In implementations, the semiconductor package 2 may be formed by a chip-first method of first forming the connection structure 300 and the semiconductor chip 100 and then forming the first redistribution structure 200 and the second redistribution structure 400.

The first redistribution structure 200 may include a plurality of first redistribution patterns 220 and a first redistribution insulating layer 230. The first redistribution insulating layer 230 may be disposed to surround the plurality of first redistribution patterns 220. In some implementations, the first redistribution structure 200 may include a plurality of first redistribution insulating layers 230 that are stacked.

In implementations, the first redistribution insulating layer 230 may include a photosensitive polymer. For example, the first redistribution insulating layer 230 may be formed of a PID or photosensitive polyimide (PSPI) or of a build-up film, such as an Ajinomoto build-up film (ABF).

The plurality of first redistribution patterns 220 may include, for example, a metal, such as Cu, aluminum (Al), W, Ti, Ta, indium (In), Mo, manganese (Mn), Co, tin (Sn), nickel (Ni), magnesium (Mg), rhenium (Re), beryllium (Be), gallium (Ga), or Ru, or an alloy of the metal but are not limited thereto.

Each of a plurality of first redistribution vias included in each of the plurality of first redistribution patterns 220 may pass through at least one first redistribution insulating layer 230 and be in contact with and connected to some of the plurality of first redistribution patterns 220. In some implementations, the plurality of first redistribution vias may have a tapered shape extending with a horizontal width gradually decreasing upward from the bottom thereof. For example, the plurality of first redistribution vias may have a horizontal width gradually increasing in the direction away from at least one semiconductor chip 100.

A plurality of under-bump structures 240 may be disposed on the lower surface of the first redistribution structure 200. A plurality of external connection terminals 500 may be attached to the plurality of under-bump structures 240, respectively. The plurality of external connection terminals 500 may connect the semiconductor package 2 to the outside. The plurality of external connection terminals 500 may include a solder ball or a solder bump.

The semiconductor chip 100 may be attached onto the first redistribution structure 200. The semiconductor chip 100 may be mounted on the first redistribution structure 200 in a flip chip manner. The semiconductor chip 100 may be electrically connected to a first redistribution pattern 220 of the first redistribution structure 200 via a lower chip pad 102.

In implementations, the semiconductor chip 100 may be a memory chip or a logic chip. The memory chip may be, for example, a volatile memory chip, such as dynamic random access memory (DRAM) or static random access memory (SRAM), or a non-volatile memory chip, such as NAND flash memory, phase-change random access memory (PRAM), magnetoresistive random access memory (MRAM), ferroelectric random access memory (FeRAM), or resistive random access memory (RRAM). In addition, the logic chip may be, for example, a microprocessor, an analog device, or a digital signal processor.

The connection structure 300 may have a mounting space 300G in which the semiconductor chip 100 is disposed, and may include a base layer 310 and a plurality of connection vias 320. The plurality of connection vias 320 may pass through the base layer 310. The connection structure 300 may be a printed circuit board (PCB), a ceramic substrate, a package manufacturing wafer, or an interposer. The connection structure 300 may include two or more stacked base layers 310, but in some implementations, may include a single base layer 310. For example, the connection structure 300 may be a multi-layer PCB.

The base layer 310 may be formed of at least one material selected from among a phenol resin, an epoxy resin, and polyimide. The base layer 310 may include at least one material selected from among, for example, flame retardant class 4 (FR-4), tetrafunctional epoxy, polyphenylene ether, epoxy/polyphenylene oxide, bismaleimide triazine (BT), Thermount, cyanate ester, polyimide, and liquid crystal polymer.

In implementations, the plurality of connection vias 320 may be formed of electrolytically deposited (ED) Cu foil, rolled-annealed (RA) Cu foil, stainless steel foil, Al foil, ultra-thin Cu foil, sputtered Cu, a Cu alloy, or the like. Each of the plurality of connection vias 320 may include a via portion 322 passing through the base layer 310 and a connection pattern portion 324 disposed on the upper surface of the base layer 310 and integrally connected to the via portion 322.

The semiconductor package 2 may further include a filling insulating layer 330 filling the mounting space 300G. The filling insulating layer 330 may fill the space between the semiconductor chip 100 disposed in the mounting space 300G and the base layer 310. For example, the filling insulating layer 330 may be formed of a thermosetting resin, such as an epoxy resin, a thermoplastic resin, such as polyimide, or a resin including a reinforcing material, such as an inorganic filler, in addition thereto, particularly, an ABF, FR-4, BT, or the like. Alternatively, the filling insulating layer 330 may be formed of a molding material, such as an epoxy mold compound (EMC), or a photosensitive material, such as a photoimageable encapsulant (PIE). In implementations, a portion of the filling insulating layer 330 may be formed of an insulating material, such as a silicon oxide film, a silicon nitride film, or a silicon oxynitride film.

The second redistribution structure 400 may include a second redistribution insulating layer 410 and a plurality of second redistribution patterns 420. The plurality of second redistribution patterns 420 may include a plurality of second redistribution vias, respectively. The second redistribution insulating layer 410 and the plurality of second redistribution patterns 420 included in the second redistribution structure 400 are generally similar to the first redistribution insulating layer 230 and the plurality of first redistribution patterns 220 included in the first redistribution structure 200, and thus, the description made above may be omitted.

The second redistribution structure 400 may further include a plurality of upper connection pads 430 disposed on the upper surface of the second redistribution structure 400. The plurality of upper connection pads 430 may include Ni or gold (Au). The second redistribution insulating layer 410 may include an opening portion 410H at an upper side of the second redistribution insulating layer 410, and the upper surface of each of the plurality of upper connection pads 430 may be exposed through the opening portion 410H.

Referring to FIG. 7, the upper surfaces (surfaces opposite to a surface on which a via is formed) of the plurality of first redistribution patterns 220 of the first redistribution structure 200 may be coplanar with one surface of the first redistribution insulating layer 230 surrounding each of the plurality of first redistribution patterns 220 including the plurality of first redistribution vias. The coplanar surfaces may be formed through the polishing process using the slurry composition SC (see FIG. 1), which is described above. Unlike shown in FIG. 7, like the first redistribution structure 200, the upper surfaces (surfaces opposite to a surface on which a via is formed) of the plurality of second redistribution patterns 420 of the second redistribution structure 400 may also be coplanar with one surface of the second redistribution insulating layer 410 surrounding each of the plurality of second redistribution patterns 420.

Referring to FIG. 8, the method of manufacturing a semiconductor package, according to implementations, may include operation S100 of forming, on a substrate, a redistribution insulating layer, which includes a PID, and in which an opening portion is defined, operation S200 of forming a preliminary redistribution pattern on the redistribution insulating layer while filling the opening portion, and operation S300 of polishing the preliminary redistribution pattern by performing a CMP process using a slurry composition, thereby forming a redistribution pattern. The slurry composition SC (see FIG. 1) may include at least one of a polymer including a hydrophobic chain and a nonionic surfactant having an HLB value of about 3 to about 10 inclusive. Herein, the slurry composition SC (see FIG. 1) is the same as described above with reference to FIG. 1.

Referring to FIGS. 7 and 8, first, the first redistribution insulating layer 230, which includes a PID, and in which an opening portion is defined, may be formed on a substrate in operation S100. The opening portion of the first redistribution insulating layer 230 may be defined to correspond to the shape of a first redistribution pattern 220 including a plurality of first redistribution vias, as shown in FIG. 7.

A preliminary redistribution pattern may be formed on the first redistribution insulating layer 230 while filling the opening portion in operation S200, and the preliminary redistribution pattern may be polished by performing a CMP process using a slurry composition, thereby forming the first redistribution pattern 220 in operation S300. Accordingly, the upper surface of the first redistribution pattern 220 may have the same vertical level as the upper surface of the first redistribution insulating layer 230, and even when a plurality of first redistribution patterns 220 and a plurality of first redistribution insulating layers 230 are stacked in the vertical direction, undulation of the semiconductor package may be prevented.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

As used herein, the term “about” with reference to a numerical value or range is intended to include values that are functionally or insignificantly different from the stated value or range, as may be attributable to variations in measurement techniques, rounding, or manufacturing or processing tolerances. Thus, a range such as “about 1 to about 10” is intended to include all values within the stated range, as well as values slightly outside the range that would be understood by a person of ordinary skill in the art to provide substantially the same effect or result.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A slurry composition comprising:
a polishing particle; and
at least one of (i) a polymer including a hydrophobic chain, or (ii) a nonionic surfactant, the nonionic surfactant having a hydrophilic-lipophilic balance (HLB) value of about 3 to about 10 inclusive.

2. The slurry composition of claim 1, wherein the polymer including the hydrophobic chain includes at least one functional group of methyl, ethyl, butyl, alkyl, fluorocarbon, cyclohexane, phenyl, benzoyl, trifluoromethyl, or cyclopentadiene.

3. The slurry composition of claim 1, wherein a molecular weight of the polymer including the hydrophobic chain is about 1,000 to about 10,000 inclusive.

4. The slurry composition of claim 1, wherein a molecular weight of the nonionic surfactant is about 1,000 to about 10,000 inclusive.

5. The slurry composition of claim 1, wherein a content of the nonionic surfactant is about 0.01 weight % to about 0.1 weight % inclusive with respect to a total content of the slurry composition.

6. The slurry composition of claim 1, wherein the slurry composition has a polishing selectivity of a metal material layer to a photo imageable dielectric (PID), the polishing selectivity being about 20 to about 50.

7. The slurry composition of claim 1, comprising at least one of:
deionized water;
a cationic chemical;
a chelate chemical;
a pH modifier;
an oxidizer; or
biocide.

8. The slurry composition of claim 7, wherein the cationic chemical includes at least one of aminobutyric acid, 4-amino benzoic acid, picolinic acid, 1,2,4-triazole, or benzotriazole.

9. The slurry composition of claim 7, wherein the chelate chemical includes at least one of an amino acid or a carboxylic group.

10. The slurry composition of claim 9, wherein the amino acid includes at least one of glycine, aniline, proline, lysin, arginine, or histidine, and wherein the carboxylic group includes a citric acid.

11. A method of manufacturing a semiconductor device, the method comprising:
forming a hydrophobic insulating layer on a substrate;
forming, on the hydrophobic insulating layer, an object to be polished; and
polishing the object by performing a chemical mechanical polishing process using a slurry composition,
wherein the slurry composition includes at least one of (i) a polymer including a hydrophobic chain, or (ii) a nonionic surfactant, the nonionic surfactant having a hydrophilic-lipophilic balance (HLB) value of about 3 to about 10 inclusive.

12. The method of claim 11, wherein the object includes a metal material layer.

13. The method of claim 12, wherein the object includes copper, and the hydrophobic insulating layer includes a photo imageable dielectric (PID).

14. The method of claim 11, wherein at least a portion of the object fills an opening portion defined in the hydrophobic insulating layer, and
wherein polishing the object comprises polishing the object such that an upper surface of the hydrophobic insulating layer has a same vertical level as an upper surface of the object.

15. The method of claim 11, wherein the polymer including the hydrophobic chain includes at least one functional group of methyl, ethyl, butyl, alkyl, fluorocarbon, cyclohexane, phenyl, benzoyl, trifluoromethyl, or cyclopentadiene.

16. The method of claim 11, wherein each of a molecular weight of the polymer including the hydrophobic chain and a molecular weight of the nonionic surfactant is about 1,000 to about 10,000 inclusive.

17. A method of manufacturing a semiconductor package, the method comprising:
forming, on a substrate, a redistribution insulating layer that includes a photo imageable dielectric (PID), the PID defining an opening portion;
forming a preliminary redistribution pattern on the redistribution insulating layer, a portion of the preliminary redistribution pattern filling the opening portion; and
forming a redistribution pattern by performing a chemical mechanical polishing process on the preliminary redistribution pattern using a slurry composition,
wherein the slurry composition includes at least one of (i) a polymer including a hydrophobic chain, or (ii) a nonionic surfactant, the nonionic surfactant having a hydrophilic-lipophilic balance (HLB) value of about 3 to about 10 inclusive.

18. The method of claim 17, wherein the slurry composition has a polishing selectivity of the preliminary redistribution pattern to the PID of about 20 to about 50.

19. The method of claim 17, wherein forming the redistribution pattern comprises polishing the preliminary redistribution pattern by using the redistribution insulating layer as a polishing stop layer.

20. The method of claim 19, comprising:
before forming the preliminary redistribution pattern, forming a seed layer covering the redistribution insulating layer,
wherein the slurry composition includes at least one of deionized water, a cationic chemical, a chelate chemical, a pH modifier, an oxidizer, or biocide.
